(19) United States
(12) Patent Application Publication
(10) Pub. No.: US 2005/0170735 A1
(43) Pub. Date: Aug. 4, 2005

(54) Manufacture of flat panel light emitting devices

(76) Inventor: David R. Strip, Albuquerque, NM (US)

Correspondence Address: Paul A. Leipold;Patent Legal Staff, Eastman Kodak Company, 343 State Street, Rochester, NY, 14650-2201, US

(21) Appl. No.: 10/772,203

(22) Filed: Feb. 4, 2004

(51) Int. Cl. H05B 33/10

(52) U.S. Cl. 445/24; 445/25

(57) ABSTRACT

A method of manufacturing a flat panel light emitting device of a predetermined size includes forming an area of light emitting materials on a substrate, the area being larger than the predetermined size; detecting defects in the area; determining a defect free portion of the area having the predetermined size; and cutting the defect free portion from the substrate to produce the flat panel light emitting device.

### FIELD OF THE INVENTION

The present invention relates to the manufacture of flat panel light emitting devices such as displays and extended light sources, an example being organic light emitting diode displays, backlights and area illumination sources and, more particularly, to the patterned deposition of materials such as organic light emitting materials on a substrate.

### BACKGROUND OF THE INVENTION

Organic light emitting diode (OLED) light sources and displays are known. Such light sources and displays are constructed by depositing and treating multiple layers of materials such as organic materials on a substrate. When a current is passed through the multiple layers of organic materials, light is emitted. The color of light is dependent on the type of materials and or any color filters that are formed over the light emitting materials.

The deposition of the layers of organic materials in an OLED device is difficult. Small-molecule OLED materials are typically deposited by evaporation from a source onto a substrate in a vacuum. The materials are sensitive to moisture and other contaminants and must be carefully patterned at a high resolution to enable a pixilated display capable of, for example, displaying images. Despite careful control of the manufacturing environment and preparation of materials, defects are present in the coated materials. The frequency and distribution of defects will determine the yield of good product.

There is a need therefore for an improved method for making flat panel light emitting devices.

### SUMMARY OF THE INVENTION

The need is met according to the present invention by providing a method of manufacturing a flat panel light emitting device of a predetermined size that includes forming an area of light emitting materials on a substrate, the area being larger than the predetermined size; detecting defects in the area; determining a defect free portion of the area having the predetermined size; and cutting the defect free portion from the substrate to produce the flat panel light emitting device.

### ADVANTAGES

The present invention has the advantage that it provides a method for manufacturing flat panel light emitting devices that optimizes the use of materials in the presence of defects.

### BRIEF DESCRIPTION OF THE DRAWINGS

FIG. 1 is a schematic plan view of an array of light emitting devices used in the method of the present invention;

FIG. 2a is a schematic plan view of a light emitting device having a predetermined size cut from the array;

FIG. 2b is a schematic plan view of a light emitting device having a different predetermined size cut from the array;

FIG. 2c is a schematic plan view of a light emitting device having a second different predetermined size cut from the array;

FIG. 3 is a schematic plan view of an array of light emitting devices showing different sized portions to be cut from the array;

FIG. 4 is a schematic plan view of a cell design containing a single light emitting element;

FIG. 5 is a schematic plan view of a repeated pattern of the cell shown in FIG. 4;

FIG. 6 is a schematic plan view and associated section of a different cell design;

FIG. 7 is a schematic plan view of a cell which contains three different colored light emitting elements;

FIG. 8 is a schematic plan view of a cell which is hexagonal in shape;

FIG. 9 is a schematic plan view of an array of light emitting elements utilizing two different cell shapes;

FIG. 10 is a schematic plan view of an array of linear light emitting devices used in the method of the present invention;

FIG. 11 is a schematic diagram showing apparatus for practicing the method of the present invention;

FIG. 12 is a schematic plan and section view of a completed light emitting flat panel device;

FIG. 13 is a schematic diagram of a typical OLED device structure;

FIG. 14 is a schematic plan view and associated section showing the formation of a series connection from the cell design of FIG. 6; and

FIG. 15 illustrates a detail of an apparatus to practice the invention.

### DETAILED DESCRIPTION OF THE INVENTION

Referring to FIG. 1, according to one embodiment of the present invention, an array of light emitting elements 2 is formed on a substrate 1. In a less than perfect process, defects, indicated by X's will cause some of the light emitting elements 3 to be unacceptable for the intended purpose. The frequency and spatial distribution of these defects in light emitting elements will be a function of a large number of process variables and their locations will be random or regular according to the nature of the cause of the defect.

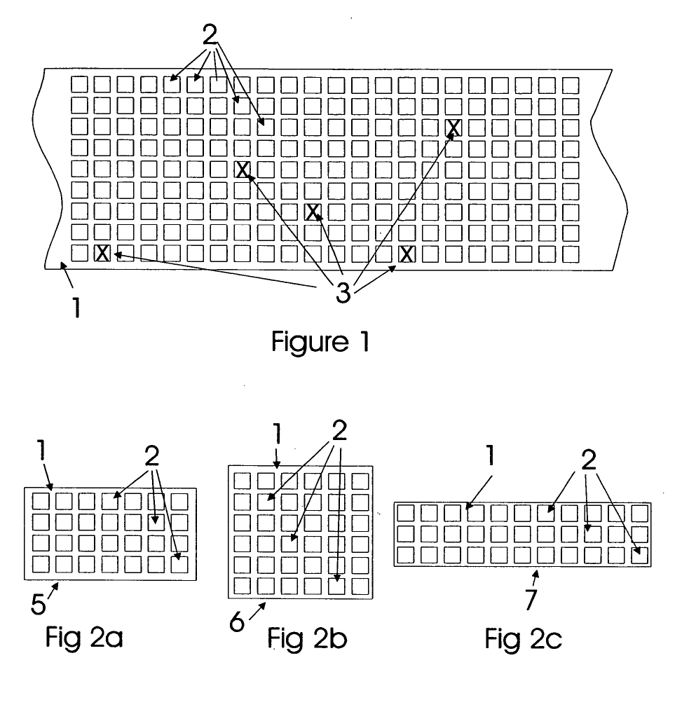

If it is desired to produce light emitting devices of a predetermined size and the area of light emitting elements on the substrate is larger than the area of the light emitting devices to be produced, it may be possible to cut defect free light emitting devices of the predetermined size from the substrate. For example, FIGS. 2a, 2b, and 2c show light emitting devices having three different sizes with different numbers and arrangements of light emitting elements 2.

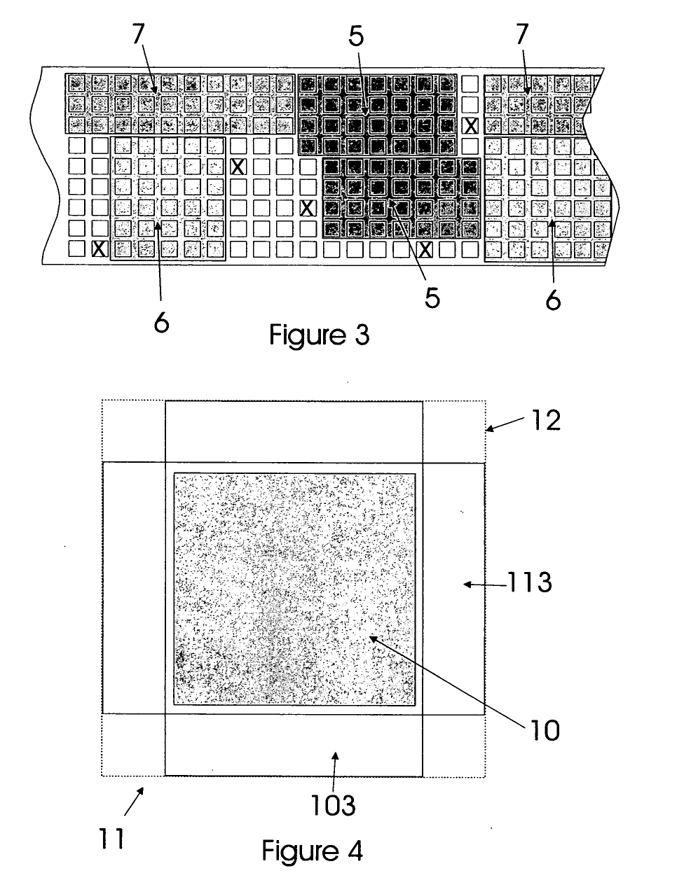

In a typical manufacturing scenario, a mix of the three different light emitting devices is desired in some particular quantities. For example, for every 10 units of the device in FIG. 2a, we also desire 7 units of the device in FIG. 2b, and 3 units of the device in FIG. 2c. A best arrangement of these device patterns on the substrate such that no two overlap and none contains any of the defective light emitting elements can be found using known search techniques. FIG. 3 shows one possible arrangement of the devices of predetermined sizes 5, 6, and 7 overlaid on the array of light emitting elements on the substrate while avoiding the defective elements marked with an X.

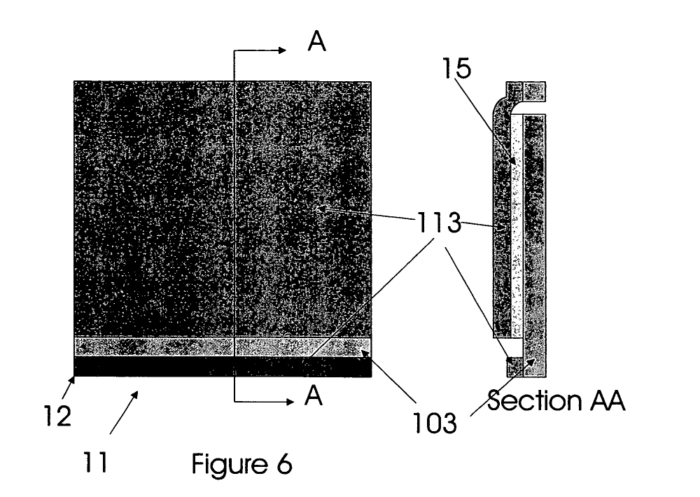

Referring to FIG. 4, a cell 11 containing a single light emitting element is defined within a cell boundary 12. The single light emitting element contains an anode 103 and a cathode 113 each of which extend to the cell boundary 12. A layer of light emitting material 15 (see FIG. 6) is provided between the anode and cathode to define a light emitting region 10 at the intersection of the anode 103 and cathode 113.

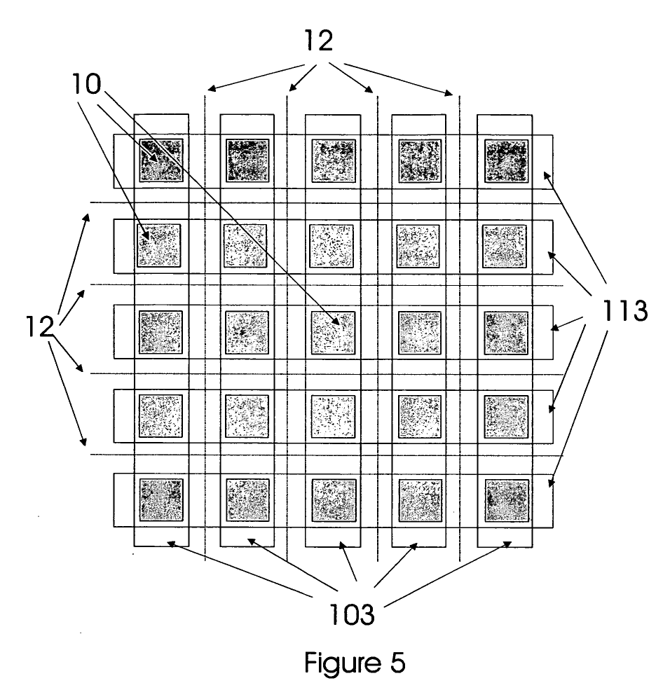

FIG. 5 shows an array of light emitting elements 2 in which each element is a replica of the cell shown in FIG. 4. By replicating the pattern at intervals equal to the dimensions of the cell boundary 12, electrical connectivity is provided in two directions. This pattern can now be cut apart along cell boundaries 12 to create electrically connected devices of predetermined sizes. This pattern would be appropriate for producing passive matrix displays, among other uses. For example, the pattern could be produced with a white emitter, then covered with a color filter array to produce a full color display. Alternatively, the pattern could be produced using red, green, and blue emitters to create an RGB pixel grouping.

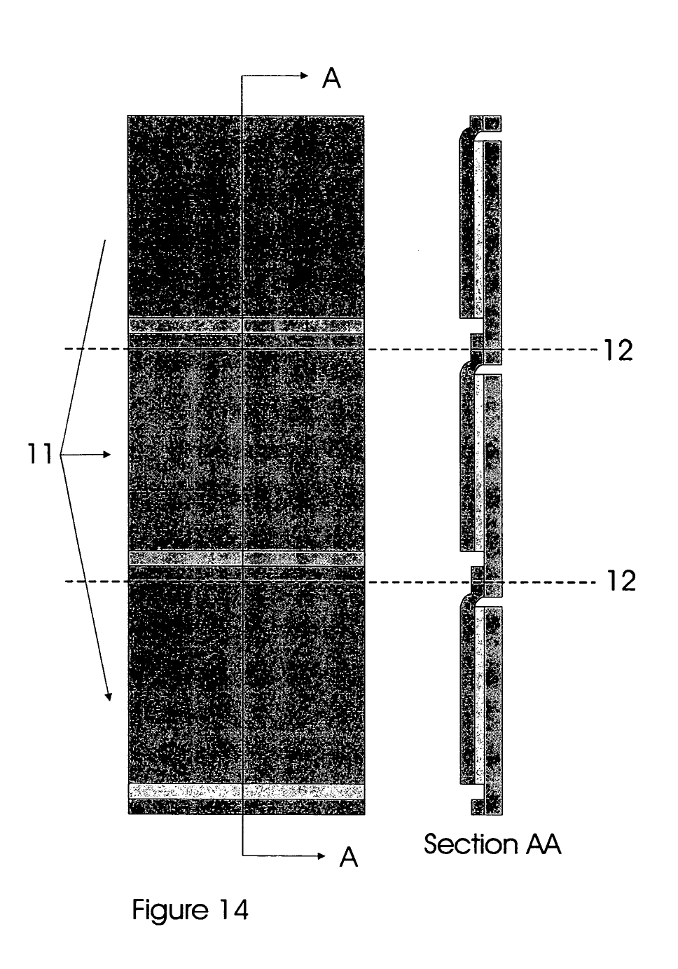

FIG. 6 shows a different embodiment of a cell design which connects the light emitting elements in a series connection when patterned at intervals equal to the cell boundary dimension as shown in FIG. 14. For devices such as OLEDs which tend to fail as a short, this arrangement is a familiar approach to fault tolerance, especially for cases in which the supply voltage is available at many multiples of the device voltage.

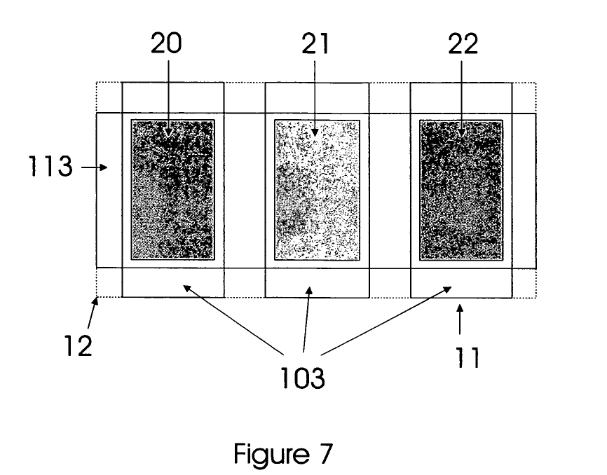

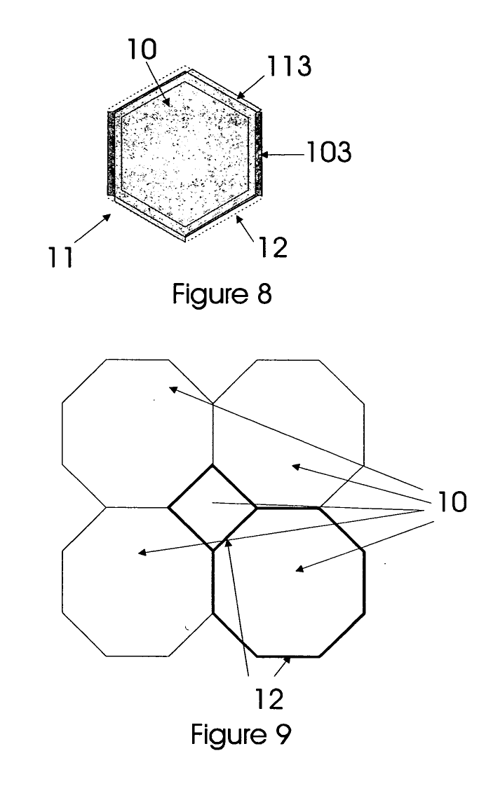

FIG. 7 shows a different embodiment of a cell design which contains three light emitting regions: red 20, green 21, and blue 22. This embodiment illustrates that the cell is not constrained to contain a single light emitting region and that the cell does not have to be square. This pattern would be appropriate for making tri-color (RGB) passive matrix displays. FIG. 8 shows an embodiment utilizing a hexagonal cell. Hexagonal cells are known for the ability to tile the plane efficiently. This further illustrates the freedom in designing the cell shape. FIG. 9 shows an array that is generated from two different cell shapes 12, an octagon, and a square.

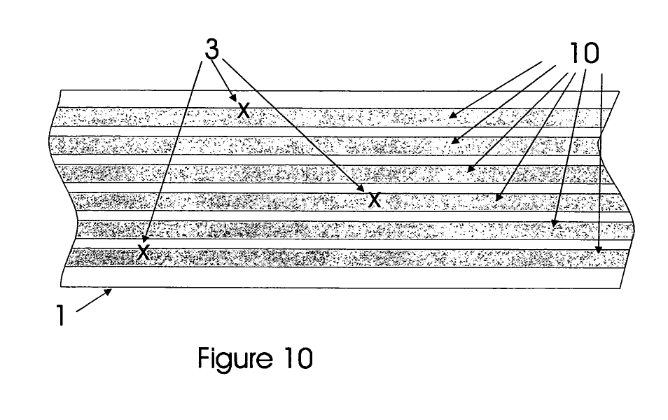

FIG. 10 shows an embodiment in which the light emitting regions 10 are linear in shape. For substrates 1 which are continuous in form, the linear shape would also be continuous in extent. This form is particularly useful when combined with the design of FIG. 6, which can be implemented to create linear elements connected in series in the transverse direction of the substrate. The defects 3 are identified by X's as before and a cutting pattern of the desired sizes is developed to avoid the defects.

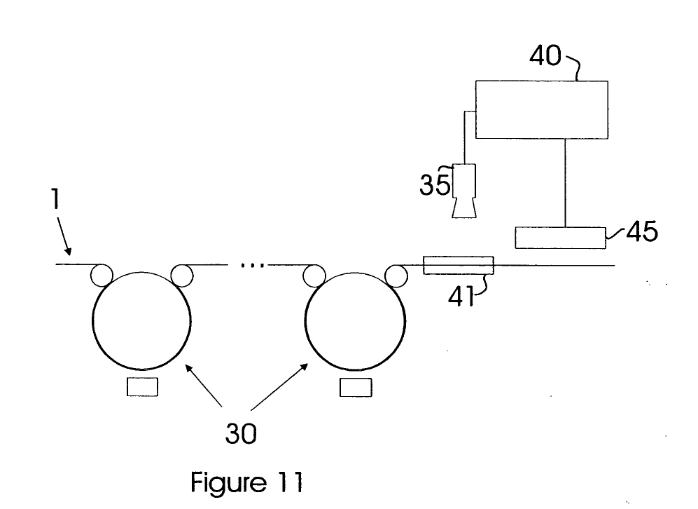

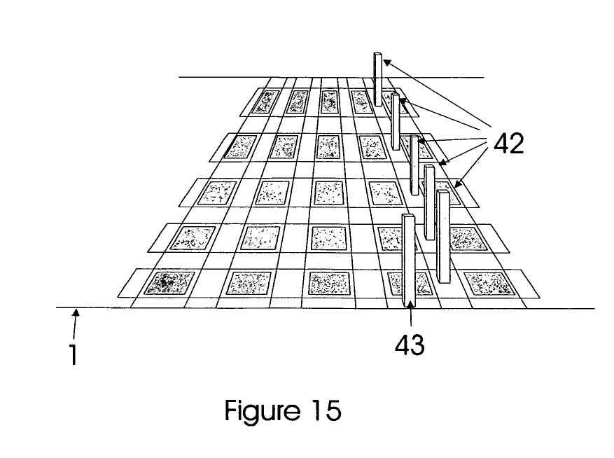

FIG. 11 shows an apparatus for practicing the present invention. In the embodiment shown, a flexible substrate 1 is fed through a plurality of coating stations 30 where thin films are deposited on the substrate to form the OLED light emitting devices. After the final coating, the substrate is advanced to a test station 41. FIG. 15 shows one embodiment for applying power to test the pattern shown in FIG. 5. As the substrate advances through the test station 41, row power contacts 42 and column power contact 43 intermittently contact the device and apply current, either simultaneously to all row power contacts 42, sequentially, or in other combinations. As illustrated in this embodiment, as power is applied to cells in the test station video camera 35 captures an image of the devices within the test station and transmits that image to a computer 40. The configuration shown in FIGS. 11 and 15 allows testing of both continuous and sheet substrates without first cutting the devices in smaller components.

Programs executing on the computer analyze the image using methods well-known in the field of computer vision to determine which devices are defective. The locations of the defects and a list of desired product sizes are utilized to define a cutting pattern for producing the light emitting devices from the substrate. Algorithms known in the field of cutting stock are used to determine a layout which indicates where to cut the substrate into the desired product sizes. (For example, see Cheng, C. H.; Feiring, B. R.; Cheng, T. C. E. (1994): The Cutting Stock Problem A Survey, International Journal of Production Economics 36: 291-305.) FIG. 3, e.g., illustrates one such layout. The computer 40 sends instructions to the punch 45 which cuts the substrate into the desired product sizes according to the layout.

It is understood that this is just one of many ways to provide an apparatus for practicing this invention. For example, although FIG. 11 shows a flexible substrate 1, the substrate might be rigid and in discrete sheets, it might be flexible and in roll form, or it might be flexible in discrete sheets. There are other possibilities relating to the substrate. A particular configuration of coating station 30 is shown in FIG. 11. Numerous other configurations exist and include both stationary and non-stationary deposition sources. The embodiment described utilizes a video camera 35. Other forms of sensors may work as well, including linear scanning cameras as well as other imaging and non-imaging sensor technologies. The computer program which analyzes the sensor data will have different forms depending on the nature of the sensor. The punch 45 shown in the figure can be a mechanical punch, slitter, or chopper, mounted on actuated guides to allow the desired material to be removed. Other embodiments might utilize a laser, a waterjet cutter, or other cutting mechanisms.

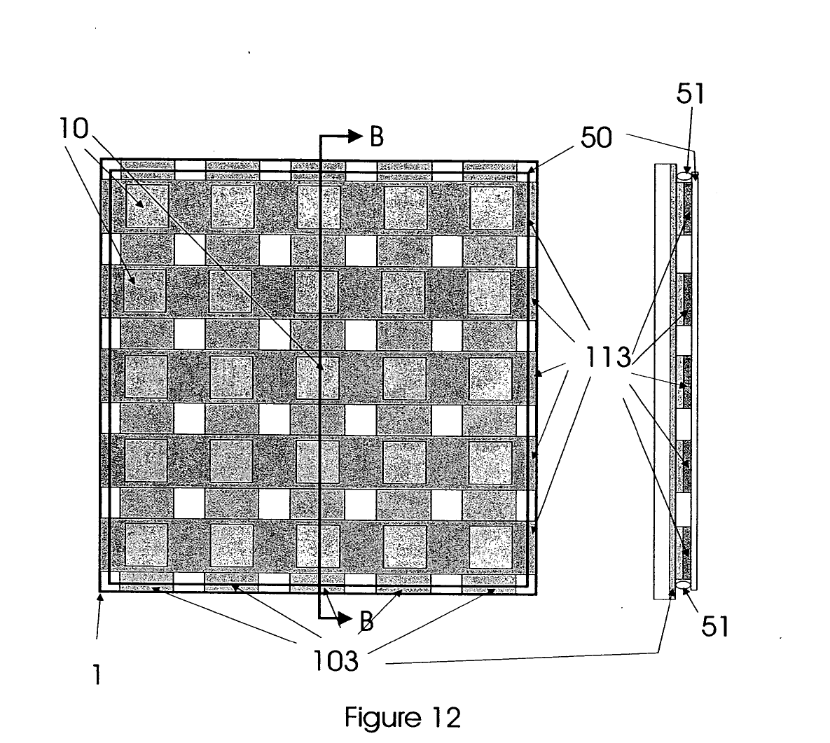

FIG. 12 shows a completed light emitting flat panel device produced according to this invention. Based upon instructions from the computer 40, the punch 45 has cut the substrate 1 to the predetermined size. A cover glass 50 is place over the coated substrate 1 and bonded using a UV-cure epoxy weld 51. It is understood that there are many alternative embodiments of flat panel devices practicing this invention. For example, in place of a cover glass, an metal cover may be used. A desiccant may be introduced between the cover and the completed OLED device. Alternative sealing methods may be used, such as melted glass frit or glass-glass soldering. For some cell designs an alternative method may be required to provide electrical contacts outside the cover glass. These methods may include wire bonding to the cell conductors, performed in a manner common in making connections to semiconductor components. Alternatively, an additional coating step may be applied after the identification of a desired cutting pattern. This coating step would provide electrical contact between cells in the predetermined pattern and the region of the substrate outside the cover glass. For some patterns it may be necessary to remove coatings from the peripheral region of the predetermined pattern. This could be accomplished with laser ablation, mechanical scribing, solvents, or other means.

Applied materials may include light emitting materials such as organic materials used in the manufacture of organic light emitting diode (OLEDs) displays or light sources. Other materials may include semiconductor materials, conductive materials such as metals, active species such as chemicals that interact with thin films of deposited materials, for example to provide means for removal of materials or to encapsulate or seal a layer.

The present invention may also be combined with other coating or deposition methods known in the art, for example curtain coating, to deposit or process other materials. In addition the invention may be used to selectively modify the substrate for adhesion, electrical properties, dopants and other desirable treatments. Existing methods for cutting, sealing, bonding, and packaging the substrate may also be employed.

In a preferred embodiment, the invention is employed in a device that includes Organic Light Emitting Diodes (OLEDs) which are composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light emitting displays can be used to fabricate such a device.

General Device Architecture

The present invention can be employed in most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

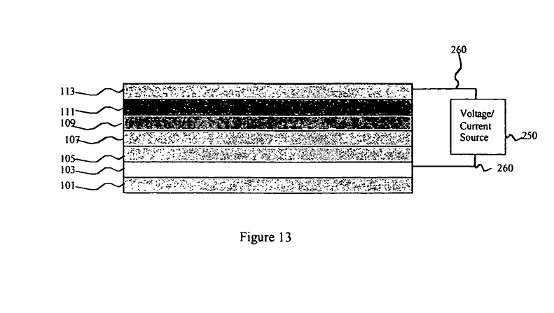

There are numerous configurations of the organic layers wherein the present invention can be successfully practiced. A typical structure is shown in FIG. 13 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. The total combined thickness of the organic layers is preferably less than 500 nm.

The anode and cathode of the OLED are connected to a voltage/current source 250 through electrical conductors 260. The OLED is operated by applying a potential between the anode and cathode such that the anode is at a more positive potential than the cathode. Holes are injected into the 10 organic EL element from the anode and electrons are injected into the organic EL element at the anode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate where either the cathode or anode can be in contact with the substrate. The electrode in contact with the substrate is conveniently referred to as the bottom electrode. Conventionally, the bottom electrode is the anode, but this invention is not limited to that configuration. The substrate can either be transmissive or opaque. In the case wherein the substrate is transmissive, I reflective or light absorbing layer is used to reflect the light through the cover or to absorb the light, thereby improving the contrast of the display. Substrates can include, but are not limited to, glass, plastic, semiconductor materials, silicon, ceramics, and circuit board materials. Of course it is necessary to provide a light-transparent top electrode.

Anode

When EL emission is viewed through anode 103, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful to provide a hole-injecting layer 105 between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis{N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 109 of the organic EL element includes a luminescent or fluorescent material where electroluminescence is produced as a result of electron-hole pair recombination in this region. The light-emitting layer can be comprised of a single material, but more commonly consists of a host material doped with a guest compound or compounds where light emission comes primarily from the dopant and can be of any color. The host materials in the light-emitting layer can be an electron-transporting material, as defined below, a hole-transporting material, as defined above, or another material or combination of materials that support hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Polymeric materials such as polyfluorenes and polyvinylarylenes (e.g., poly(p-phenylenevinylene), PPV) can also be used as the host material. In this case, small molecule dopants can be molecularly dispersed into the polymeric host, or the dopant could be added by copolymerizing a minor constituent into the host polymer.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material. For phosphorescent emitters it is also important that the host triplet energy level of the host be high enough to enable energy transfer from host to dopant.

Host and emitting molecules known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo{f}-8-quinolinolato]zinc(II)
CO-4: Bis(2-methyl-8-quinolinolato)aluminum(III)-μ-oxo-bis(2-methyl-8-quinolinolato)aluminum(III)
CO-5: Indium trisoxine [alias, tris(8-quinolinolato)indium]
CO-6: Aluminum tris(5-methyloxine) [alias, tris(5-methyl-8-quinolinolato)aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Other classes of useful host materials include, but are not limited to: derivatives of anthracene, such as 9,10-di-(2-naphthyl)anthracene and derivatives thereof as described in U.S. Pat. No. 5,935,721, distyrylarylene derivatives as described in U.S. Pat. No. 5,121,029, and benzazole derivatives, for example, 2,2′, 2″-(1,3,5-phenylene)tris[1-phenyl-1H-benzimidazole]. Carbazole derivatives are particularly useful hosts for phosphorescent emitters.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds.

Electron-Transporting Layer (ETL)

Preferred thin film-forming materials for use in forming the electron-transporting layer 111 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182.

Additional layers such as electron or hole-blocking layers as taught in the art may be employed in devices of this invention. Hole-blocking layers are commonly used to improve efficiency of phosphorescent emitter devices, for example, as in US 20020015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357) and inkjet method (U.S. Pat. No. 6,066,357).

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or an electrode protection layer beneath the cover.

The invention has been described in detail with particular reference to certain preferred embodiments thereof, but it will be understood that variations and modifications can be effected within the spirit and scope of the invention.

### PARTS LIST

1 substrate
2 light emitting elements
3 defects in light emitting elements
5 device of first predetermined size
6 device of second predetermined size
7 device of third predetermined size
10 light emitting regions
11 cell
12 cell boundary
15 organic layers
20 red light emitting region
21 green light emitting region
22 blue light emitting region
30 coating station
35 video camera
40 computer
41 test station
42 row power contacts
43 column power contact
45 punch
50 cover glass
51 UV-cure epoxy weld
101 substrate
103 anode layer
105 hole-injecting layer
107 hole-transporting layer
109 light-emitting layer
111 electron-transporting layer
113 cathode layer
250 voltage/current source
260 conductive wiring

1. A method of manufacturing a flat panel light emitting device of a predetermined size, comprising:
a) forming an area of light emitting materials on a substrate, the area being larger than the predetermined size;
b) detecting defects in the area;
c) determining a defect free portion of the area having the predetermined size; and
d) cutting the defect free portion from the substrate to produce the flat panel light emitting device.

2. The method of claim 1, wherein the device is an area illumination light source.

3. The method of claim 2, wherein the light emitting area includes a plurality of light emitting elements that are connected in series.

4. The method of claim 1 wherein the device is a display having a plurality of light emitting elements.

5. The method of claim 4 wherein the device is a display.

6. The method of claim 4 wherein the device is an area illumination light source.

7. The method of claim 5 wherein the light emitting elements are arranged in triplets that emit red, green, or blue light.

8. The method of claim 1, wherein the substrate is a web.

9. The method of claim 1, wherein the substrate is a discrete sheet.

10. The method of claim 1, wherein the substrate is flexible.

11. The method of claim 1, wherein the substrate is rigid.

12. The method of claim 1, wherein the light emitting elements are OLEDs.

13. The method of claim 1, wherein the light emitting area includes a plurality of identically shaped light emitting elements.

14. The method of claim 1, wherein the light emitting area includes a plurality of differently shaped light emitting elements.

15. The method of claim 1, wherein the light emitting elements are elongated strips.

16. The method of claim 1, further comprising the step of determining a maximum number of defect free portions that can be cut from the array.

17. The method of claim 1, wherein the light emitting device can have one of a plurality of predetermined sizes, and further comprising the step of determining an optimum arrangement of defect free portions of one or more of the predetermined sizes to be cut from the array.

18. The method of claim 1, wherein the light emitting device includes electrical contacts, and further comprising the steps of
a. providing a cover over the light emitting device, leaving electrical contacts extending beyond the cover, and
b. sealing the cover to the substrate to encapsulate the light emitting materials between the substrate and the cover.

19. The method of claim 18, further comprising the step of removing overlying materials to expose the electrical contacts beyond the cover.

20. The method of claim 1, wherein the area of light emitting materials defines a plurality of light emitting elements and further comprising the steps of:
a) providing electrical conductors between the light emitting elements and the periphery of the defect free portion;
b) providing a cover over the light emitting device, leaving the electrical conductors extending beyond the cover, and c) sealing the cover to the substrate to encapsulate the light emitting materials between the substrate and the cover.

21. The method of claim 20, further comprising the step of removing overlying materials to expose the electrical contacts beyond the cover.
